(19) United States
(12) Patent Application Publication
(10) Pub. No.: US 2009/0163013 A1
(43) Pub. Date: Jun. 25, 2009

(54) Method for Forming Gate of Non-Volatile Memory Device

(75) Inventors: Seok Pyo Song, Seongnam-si (KR); Dong Sun Sheen, Yongin-si (KR); Seung Ho Pyi, Yongin-si (KR); Ki Seon Park, Yongin-si (KR); Sun Hwan Hwang, Icheon-si (KR); Mi Ri Lee, Icheon-si (KR); Gil Jae Park, Busan (KR)

Correspondence Address: MARSHALL, GERSTEIN & BORUN LLP, 233 SOUTH WACKER DRIVE, 6300 SEARS TOWER, CHICAGO, IL, 60606-6357, US

(73) Assignee: HYNIX SEMICONDUCTOR INC., Icheon-si (KR)

(21) Appl. No.: 12/131,558

(22) Filed: Jun. 2, 2008

(30) Foreign Application Priority Data
Dec. 21, 2007 (KR) 10-2007-0135871

(51) Int. Cl. H01L 21/28

(52) U.S. Cl. 438/591; 257/E21.21

(57) ABSTRACT

Provided is a method for forming a gate of a non-volatile memory device. A tunneling layer, a charge trapping layer, a blocking layer, and a control gate layer are formed on a semiconductor substrate. A hard mask is formed on the control gate layer. The hard mask defines a region on which a gate is formed. A gate pattern is formed by etching the control gate layer, the blocking layer, the charge trapping layer, and the tunneling layer. A damage compensation layer on a side of the gate pattern is formed using ultra low pressure plasma of a pressure range from approximately 1 mT to approximately 100 mT.

### CROSS-REFERENCE TO RELATED APPLICATION

The priority of Korean patent application number 10-2007-0135871, filed on Dec. 21, 2007, which is incorporated by reference in its entirety, is claimed.

### BACKGROUND OF THE INVENTION

1. Field of the Invention

The present invention relates to a method for forming a non-volatile memory device, and more particularly, to a method for forming a gate of a non-volatile memory device having a charge trapping layer.

2. Brief Description of Related Technology

Generally, a semiconductor memory device for storing data is classified into a volatile memory device or a non-volatile memory device. A volatile memory device loses its stored data when no power is applied, but a non-volatile memory device still retains its stored data when no power is applied. A non-volatile memory device is extensively used in a mobile phone system, a memory card for storing music and/or image data, and other applicable devices under conditions where power may not be always supplied, or only low power is required. A representative example of a non-volatile memory device is a block erasable flash memory.

A flash memory device has a cell transistor that typically includes a stacked gate structure, like a conventional non-volatile memory device. A representative example of a stacked gate structure is a floating gate structure capping a polysilicon film with an inter-poly oxide (IPO). Because a floating gate flash memory device has excellent extendibility, a multi-level chip is under development in recent times. However, as a floating gate flash memory device is highly drastically integrated lately, interference or coupling becomes seriously problematic, which drastically changes a threshold voltage according to a charge state of adjacent cells. Accordingly, a new cell structure has been attempted to resolve the interference between adjacent cells.

A non-volatile memory device having a charge trapping layer is attracting much interest in the semiconductor industry. In a charge trapping layer interference occurs less between cells even with higher integration. A non-volatile memory device having a charge trapping layer typically has a structure where a tunneling layer, a charge trapping layer, a blocking layer, and a control gate electrode are sequentially stacked on a substrate having a channel region.

On the other hand, as a design rule of a semiconductor device is gradually reduced, an etching process for forming a gate pattern becomes more difficult and complex. For example, to form a gate structure of a charge trapping non-volatile memory device, after sequentially stacking a tunneling layer, a charge trapping layer, a blocking layer, and a control gate electrode layer, a process for patterning stacked structures in a required scale according to a design rule is necessary. This patterning process includes a dry etching process that typically requires high energy. During this patterning process, a multiple layers of a gate structure can be damaged. Specifically, the damage may mostly occur at edge portions of the structure, between the charge trapping layer and the tunneling layer.

In a charge trap non-volatile memory device, the charge storage characteristic (i.e., retention) is a very important factor that determines device characteristics. The charge storage characteristic prevents electrons trapped in the charge trapping layer from leaking toward adjacent cells or the upper part of the layer during cycling in which a program or erase operation repeats. If electrons, trapped in a charge trapping layer through a program operation, transfer to adjacent cells during a read operation, a threshold voltage of a memory cell changes. As a result, defective devices can be manufactured. The damage of a charge trapping layer or a tunneling layer, occurring during a gate patterning process, causes charge loss. Therefore, there needs to be a process for removing the damage through a thermal treatment after performing a gate patterning process.

Recently, besides a conventional polysilicon or tungsten silicide (Wsi), new low resistance gate materials such as tungsten (W), titanium nitride (TiN), tantalum nitride (TaN), and ruthenium (Ru) are used to resolve resistance limitations occurring as the line width of a gate becomes smaller with the decrease of a design rule. Accordingly, the difficulty of a gate etching process drastically increases, and a process for removing the damage to a gate pattern during an etching process becomes more complex.

A method for removing the damage to a gate pattern, which occurs during a gate etching process, oxidizes a sidewall of the gate pattern by using a high temperature plasma. However, because the oxidation reaction occurs very fast in new, low-resistance gate conductors, it is especially difficult to selectively oxidize only a damaged portion when a high temperature plasma is applied. Especially, when tungsten is used as a gate conductor, oxidation reaction of tungsten occurs easily and fast. Therefore, even if silicon nitride is used as a passivation layer, characteristics of a gate can be deteriorated.

### SUMMARY OF THE INVENTION

Embodiments of the present invention are directed to a method for forming a gate of a non-volatile memory device capable of removing an etching damage of a gate pattern occurring during a gate etching process, without deterioration of device characteristics.

In one embodiment, a method for forming a gate of a non-volatile memory device includes: forming a tunneling layer, a charge trapping layer, a blocking layer, and a control gate layer on a semiconductor substrate; forming a hard mask on the control gate layer, the hard mask defining a region on which a gate is formed; etching the control gate layer, the blocking layer, the charge trapping layer, and the tunneling layer to form a gate pattern; applying an ultra low pressure plasma of a pressure range from approximately 1 mT to approximately 100 mT to a side of the gate pattern to form a damage compensation layer.

The control gate layer may include one of a polysilicon film, a tungsten (W) film, a tungsten silicide (WSi) film, a tungsten nitride (WN) film, a tantalum nitride (TaN) film, a titanium nitride (TiN) film, a ruthenium (Ru) film, and a stacked structure thereof.

The forming of the damage compensation layer may include oxidizing the side of the gate pattern using a high density plasma (HDP) method, preferably at a pressure ranging from approximately 1 mT to approximately 100 mT and at a temperature ranging from approximately 200° C. to approximately 500° C. oxidation may be performed using one of oxygen (O₂), helium (He), argon (Ar), hydrogen (H₂) and a combination thereof.

The compensation layer may allow an oxide layer to be formed on the side of the gate pattern, the oxide layer having a thickness that ranges from approximately 10 Å to approximately 100 Å.

The charge trapping layer may include a stoichiometric silicon nitride (Si₃N₄) film, a silicon (Si)-rich silicon nitride (SiₓN_{y}) film, or a stacked structure of the stoichiometric silicon nitride (Si₃N₄) film and the silicon (Si)-rich silicon nitride (SiₓN_{y}) film.

### BRIEF DESCRIPTION OF THE DRAWINGS

FIGS. 1 to 3 illustrate a method for forming a gate of a non-volatile memory device having a charge trapping layer according to one embodiment of the present invention.

### DESCRIPTION OF SPECIFIC EMBODIMENTS

Hereinafter, a method for forming a gate of a non-volatile memory device having a charge trapping layer in accordance with the present invention will be described in detail with reference to the accompanying drawings.

The present invention is characterized by compulsorily oxidizing the side of a gate pattern by generating oxygen radicals with an ultra low pressure plasma, and then extracting a by-product at an ultra low pressure.

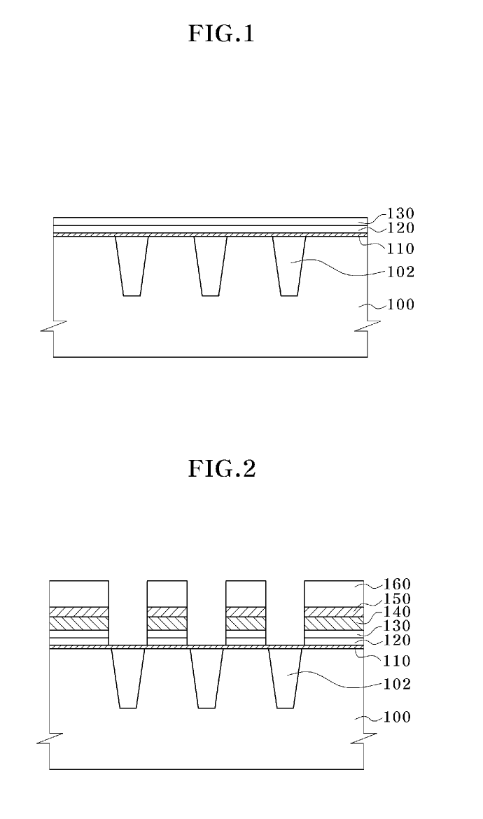

Referring to FIG. 1, a tunneling layer 110 is formed on a semiconductor substrate 100 where a device isolation layer 102 is formed. The tunneling layer 110 may be an oxide formed by using a wet oxidation process, a dry oxidation process, or a radical oxidation process. After forming the tunneling layer 110, interface characteristic between the semiconductor substrate 100 and the tunneling layer 110 can be improved by annealing under a nitric oxide (NO) or nitrous oxide (N₂O) atmosphere.

Next, a charge trapping layer 120 is formed on the tunneling layer 110. The charge trapping layer 120 may include a stoichiometric silicon nitride (Si₃N₄) film, a silicon (Si)-rich silicon nitride (SiₓN_{y}) film, or a stacked structure of the stoichiometric silicon nitride (Si₃N₄) film and the silicon (Si)-rich silicon nitride (SiₓN_{y}) film.

Then, a blocking layer 130 is formed on the charge trapping layer 120 to prevent electrons trapped in the charge trapping layer 120 from escaping through a control gate electrode (shown in FIG. 2). The blocking layer 130 may have a structure including a high-k material film such as an aluminum oxide (Al₂O₃) film, and an hafnium oxide (HfO₂) or hafnium aluminum oxide (HfAlO) film.

Referring to FIG. 2, a control gate electrode 140 and a low resistance layer 150 are formed on the blocking layer 130. The control gate electrode 140 may include one of a polysilicon film doped with high concentration by using n-type impurities, and a metal film of high work function such as a tungsten (W) film, a tungsten silicide (WSi) film, a tungsten nitride (WN) film, a tantalum nitride (TaN) film, a titanium nitride (TiN) film, a ruthenium (Ru) film, and a stacked structure thereof. The low resistance layer 150 is used for lowing resistance of the control gate electrode 140, and may have a polysilicon film/tungsten silicide (TSi) film structure or a tungsten nitride (WN) film/tungsten (W) film structure.

A hard mask 160 is formed on the low resistance layer 150 to form a gate pattern. The hard mask 160 may include a silicon nitride film of a predetermined thickness. Next, using the hard mask 160 as an etch mask, the low resistance layer 150, the control gate electrode 140, the blocking layer 130, the charge trapping layer 120, and the tunneling layer 110 are etched. The etching process is performed through dry etching that utilizes high energy plasma. During this process, the sides of the above layers constituting a gate structure are damaged, thereby giving inappropriate influences on device characteristics. The damage occurring at the side of the charge trapping layer 120 is a main factor that deteriorates the data storing characteristic (i.e., retention characteristic) of a device because the damage serves as a leakage path of charges trapped in the charge trapping layer 120.

A cleansing process is conventionally performed after a gate patterning process to remove the damage to the gate pattern. But, there are many limitations in performing the cleansing process due to a newly introduced gate conductive material used for reducing a gate resistance and, therefore, the cleansing process become more complex. Accordingly, because the damage to the gate pattern is not sufficiently removed, a leakage current occurs, and the reliability of products may deteriorate. The processes described below can be performed to remove the damage to the gate pattern caused by the etching process.

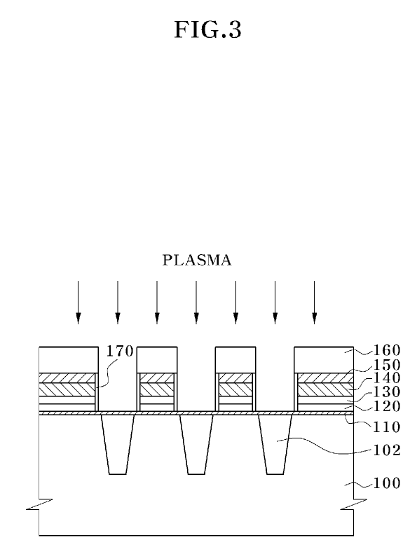

Referring to FIG. 3, when the gate pattern is damaged by dry etching, an oxide layer 170 is formed by performing a low temperature, low pressure plasma oxidation process to thinly oxidize the side of the gate pattern. The plasma oxidation process is performed by a high density plasma (HDP) method, and then oxidation reaction occurs at a temperature ranging from approximately 200° C. to approximately 500° C. A process pressure may range from approximately 1 milliTorr (mT) to approximately 100 mT. A material for forming plasma during the oxidation process is one of oxygen (O₂), helium (He), argon (Ar), hydrogen (H₂), and a combination thereof. The thickness of the oxide layer 170 on the side of a gate pattern through the plasma oxidation process may vary according to the degree of damages to the gate pattern or kinds of a gate conductive layer. The thickness of the oxide layer 170 may range from approximately 10 Å to approximately 100 Å based on silicon single crystal.

The damaged portion at the side of the gate pattern is oxidized and removed by the plasma oxidation process.

According to the present invention, the side of the gate pattern is compulsorily oxidized using low temperature, ultra low pressure plasma to generate oxygen radical. Therefore, etching damage occurring during a gate patterning process can be effectively removed without deterioration of device characteristics.

While the present invention has been described with respect to the specific embodiments, it will be apparent to those skilled in the art that various changes and modifications may be made without departing from the spirit and scope of the invention as defined in the following claims.

What is claimed is:

1. A method for forming a gate of a non-volatile memory device, the method comprising:
forming a tunneling layer, a charge trapping layer, a blocking layer, and a control gate layer over a semiconductor substrate;
forming a hard mask on the control gate layer defining a region on which a gate is formed;
etching the control gate layer, the blocking layer, the charge trapping layer, and the tunneling layer to form a gate pattern; and
applying an ultra low pressure plasma at a pressure from approximately 1 mT to approximately 100 mT to a side of the gate pattern to form a damage compensation layer on the side of the gate pattern.

2. The method of claim 1, wherein the control gate layer comprises one of a polysilicon film, a tungsten (W) film, a tungsten silicide (WSi) film, a tungsten nitride (WN) film, a tantalum nitride (TaN) film, a titanium nitride (TiN) film, a ruthenium (Ru) film, and a stacked structure thereof.

3. The method of claim 1, wherein the step of forming the damage compensation layer comprises oxidizing the side of the gate pattern by using a high density plasma (HDP) method.

4. The method of claim 3, wherein the oxidation is performed at a pressure ranging from approximately 1 mT to approximately 100 mT.

5. The method of claim 3, wherein the oxidation is performed at a temperature ranging from approximately 200° C. to approximately 500° C.

6. The method of claim 3, wherein the oxidation is performed using one of oxygen (O₂), helium (He), argon (Ar), hydrogen (H₂), and a combination thereof.

7. The method of claim 1, wherein the damage compensation layer allows an oxide layer to be formed on the side of the gate pattern, the oxide layer having a thickness that ranges from approximately 10 Å to approximately 100 Å.

8. The method of claim 1, wherein the charge trapping layer comprises a stoichiometric silicon nitride (Si₃N₄) film, a silicon (Si)-rich silicon nitride (SiₓN_{y}) film, or a stacked structure of the stoichiometric silicon nitride (Si₃N₄) film and the silicon (Si)-rich silicon nitride (SiₓN_{y}) film.
